(19) United States
(12) Patent Application Publication
(10) Pub. No.: US 2025/0040420 A1
(43) Pub. Date: Jan. 30, 2025

(54) APPARATUS FOR MANUFACTURING DISPLAY DEVICE AND METHOD OF MANUFACTURING DISPLAY DEVICE

(71) Applicant: Samsung Display Co., Ltd., Yongin-si (KR)

(72) Inventor: Dongha Lee, Yongin-si (KR)

(21) Appl. No.: 18/409,680

(22) Filed: Jan. 10, 2024

(30) Foreign Application Priority Data
Jul. 27, 2023 (KR) 10-2023-0098360

(51) Int. Cl. H10K 71/00

(52) U.S. Cl. CPC H10K 71/00

(57) ABSTRACT

An apparatus for manufacturing a display device includes: droplet ejection units for ejecting droplets; a detection unit arranged on a fall path of the droplets and configured to detect low-resolution data of droplets; and a control unit configured to determine a volume of each of the droplets based on the detected low-resolution data. The control unit includes: a machine learning unit configured to perform machine learning to determine a correlation between sample low-resolution data and sample high-resolution data of droplets; and a volume extraction unit configured to determine a volume of the falling droplets by upscaling the detected low-resolution data into upscaled high-resolution data based a result of learning by the machine learning unit. The sample high-resolution data has a magnification greater than a magnification of the sample low-resolution data.

### CROSS-REFERENCE TO RELATED APPLICATION

The present application claims priority to and the benefit of Korean Patent Application No. 10-2023-0098360, filed on Jul. 27, 2023, in the Korean Intellectual Property Office, the entire disclosure of which is incorporated by reference.

### BACKGROUND

### 1. Field

Aspects of embodiments of the present disclosure relate to an apparatus for manufacturing a display device and a method of manufacturing a display device.

### 2. Description of the Related Art

Mobility-based electronic devices have been widely used. Recently, tablet personal computers (PCs) in addition to small electronic devices, such as mobile phones, have been widely used as mobile electronic devices.

To provide and support various functions, these mobile electronic devices include a display device to provide visual information, such as an image or a video, to a user. Recently, as the sizes of components for driving a display device have been reduced, an area of the display device in an electronic device has gradually increased, and a structure that may be bent by an angle from a flat state has been developed.

### SUMMARY

Embodiments of the present disclosure include an apparatus for manufacturing a display device in which a detection unit is configured to concurrently (or simultaneously) detect a plurality of falling droplets and in which machine learning is utilized to increase the resolution of the droplets detected by the detection unit through upscaling.

However, these aspects and features are illustrative and aspects and features of the present disclosure, and problems to be solved thereby, are not limited thereto.

Additional aspects and features will be set forth, in part, in the description which follows and, in part, will be apparent from the description or may be learned by practice of the described embodiments of the present disclosure.

According to an embodiment of the present disclosure, an apparatus for manufacturing a display device includes: a plurality of droplet ejection units, each including a nozzle for ejecting droplets; a detection unit arranged on a fall path of a plurality of droplets falling from the plurality of droplet ejection units and configured to detect low-resolution data including a shape of the plurality of droplets; and a control unit configured to determine a volume of each of the plurality of droplets based on the detected low-resolution data. The control unit includes: a machine learning unit configured to perform machine learning to determine a correlation between sample low-resolution data and sample high-resolution data, the sample low-resolution data including a shape of a plurality of sample low-resolution droplets, the sample high-resolution data including a shape of high-resolution droplets corresponding to each of the plurality of sample low-resolution droplets, input to the machine learning unit; and a volume extraction unit configured to determine the volume of the plurality of droplets by upscaling the detected low-resolution data into upscaled high-resolution data based on a result of learning performed by the machine learning unit. The sample high-resolution data may have a magnification greater than a magnification of the sample low-resolution data.

The machine learning unit may include a sample data input unit, into which the sample low-resolution data and the sample high-resolution data are input, and a model type generator configured to generate an upscaling model by analyzing the correlation between the sample low-resolution data and the sample high-resolution data.

The volume extraction unit may include: an upscaling unit configured to upscale the detected low-resolution data into upscaled high-resolution data by substituting the detected low-resolution data into the upscaling model; and a volume calculation unit configured to calculate the volume of each of the plurality of droplets by extracting a three-dimensional image of the plurality of droplets based on the upscaled high-resolution data.

The number of the droplet ejection units may be greater than the number of the detection units.

The detection unit may include a first detection unit and a second detection unit facing the first detection unit with the plurality of droplets therebetween.

The first detection unit and the second detection unit may be each configured to detect a shape of a part of an outer surface of the droplets projected onto an arbitrary plane.

The control unit may be configured to calculate the outer surface of the droplets by connecting portions other than the shape of the part of the outer surface of the droplets detected by the first detection unit and the second detection unit.

The volume extraction unit may be configured to calculate a three-dimensional shape of the droplets by rotating the calculated outer surface of the droplets around the fall path of the droplets and may calculate the volume of the droplets by using the calculated three-dimensional shape of the droplets.

The detection unit may include a confocal microscope or a confocal sensor.

The apparatus may further include an accommodation unit configured to store the plurality of droplets emitted by the plurality of droplet ejection units.

According to another embodiment of the present disclosure, a method of manufacturing a display device includes: inputting, into a machine learning unit, sample low-resolution data including a shape of a plurality of sample low-resolution droplets and sample high-resolution data including a shape of high-resolution droplets corresponding to each of the plurality of sample low-resolution droplets to perform machine learning to determine the correlation between the sample low-resolution data and the sample high-resolution data; ejecting droplets by using each of a plurality of droplet ejection units, each including a nozzle; detecting, by a detection unit, low-resolution data including a shape of a plurality of droplets falling from the plurality of droplet ejection units; and determining, by a volume extraction unit, a volume of the plurality of droplets by upscaling the detected low-resolution data into upscaled high-resolution data based on a result of learning by machine learning. The sample high-resolution data may have a magnification greater than a magnification of the sample low-resolution data.

The machine learning may include: inputting sample data including the sample low-resolution data and the sample high-resolution data; and model type generating of an upscaling model by analyzing the sample low-resolution data and the sample high-resolution data.

The volume extracting may include upscaling, in which the detected low-resolution data is upscaled into the upscaled high-resolution data by substituting the detected low-resolution data into the upscaling model, and volume calculating in which the volume of each of the plurality of droplets is calculated by extracting a three-dimensional image of the plurality of droplets based on the upscaling high-resolution data.

The number of the droplet ejection units may be greater than the number of the detection units.

The detection unit may include a first detection unit and a second detection unit facing the first detection unit with the plurality of droplets therebetween.

The first detection unit and the second detection unit may be each configured to detect a shape of a part of an outer surface of the droplets projected on an arbitrary plane.

The volume extracting may include calculating an outer surface of the droplets by connecting portions other than the shape of the part of the outer surface of the droplets detected by the first detection unit and the second detection unit.

The volume extracting may include calculating a three-dimensional shape of the droplets by rotating the calculated outer surface of the droplets around a fall path of the droplets and calculating the volume of the droplets by using the calculated three-dimensional shape of the droplets.

The detection unit may include a confocal microscope or a confocal sensor.

The method may further include storing, in an accommodation unit, the plurality of droplets emitted by the droplet ejection units.

Other aspects and features of the present disclosure will be clear from the details of the drawings, the claims, and the detailed description.

### BRIEF DESCRIPTION OF THE DRAWINGS

The above and other aspects and features of embodiments of the present disclosure will be more apparent from the following description, taken in conjunction with the accompanying drawings, in which:

FIG. 1 is a perspective view schematically illustrating an apparatus for manufacturing a display device according to an embodiment;

FIG. 2 is a perspective view schematically illustrating a part of the apparatus for manufacturing a display device shown in FIG. 1;

FIG. 3 is a block diagram describing a control unit according to an embodiment;

FIG. 4 illustrates sample low-resolution data according to an embodiment;

FIG. 5 illustrates sample high-resolution data according to an embodiment;

FIG. 6 illustrates detected low-resolution data according to an embodiment;

FIG. 7 illustrates upscaled high-resolution data according to an embodiment;

FIG. 8 illustrates data for extracting the volume of droplets according to an embodiment;

FIG. 9 is a schematic flowchart describing a method of manufacturing a display device according to an embodiment;

FIG. 10 is a plan view schematically illustrating a display device manufactured by using the apparatus for manufacturing the display device according to an embodiment;

FIG. 11 is a cross-sectional view of the display device shown in FIG. 10; and

FIG. 12 is an equivalent circuit diagram of a pixel of the display panel shown in FIGS. 10 and 11 according to an embodiment.

### DETAILED DESCRIPTION

Reference will now be made in detail to embodiments, examples of which are illustrated in the accompanying drawings. The described embodiments may have different forms and should not be construed as being limited to the descriptions set forth herein. Accordingly, embodiments are merely described below, by referring to the figures, to explain aspects and features of the present description.

Because various modifications and various embodiments of the present disclosure are possible, specific embodiments are illustrated in the drawings and described in detail in the detailed description. Aspects and features of the present disclosure, and methods of achieving them, will be apparent with reference to embodiments described below in detail in conjunction with the drawings. However, the present disclosure is not limited to the embodiments disclosed herein and may be implemented in a variety of forms.

Hereinafter, embodiments of the present disclosure will be described, in detail, with reference to the accompanying drawings, and the same or corresponding components are denoted by the same reference numerals, and where the same reference numerals are assigned, redundant explanations may be omitted.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

In the following embodiments, the x-axis, the y-axis, and the z-axis are not limited to three axes on a Cartesian coordinate system and may be interpreted in a broader sense including the same. For example, the x-axis, the y-axis, and the z-axis may be perpendicular to each other but may refer to different directions that are not orthogonal to each other.

In the present disclosure, a specific process order may be performed differently from the order described. For example, two processes described in succession may be substantially performed at the same time or in an opposite order to the described order.

The control unit and/or any other relevant devices or components according to embodiments of the present disclosure described herein may be implemented utilizing any suitable hardware, firmware (e.g., an application-specific integrated circuit), software, and/or a suitable combination of software, firmware, and hardware.

For example, the various components of the control unit may be formed on one integrated circuit (IC) chip or on separate IC chips. Further, the various components of the control unit may be implemented on a flexible printed circuit film, a tape carrier package (TCP), a printed circuit board (PCB), or formed on a same substrate as the control unit. Further, the various components of the control unit may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device or the functionality of a particular computing device may be distributed across one or more other computing devices without departing from the scope of the exemplary embodiments of the present disclosure.

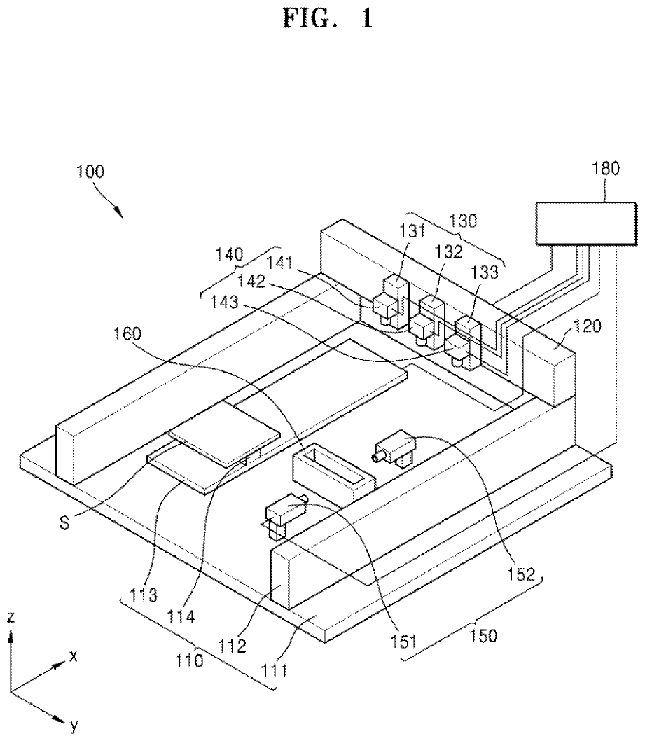

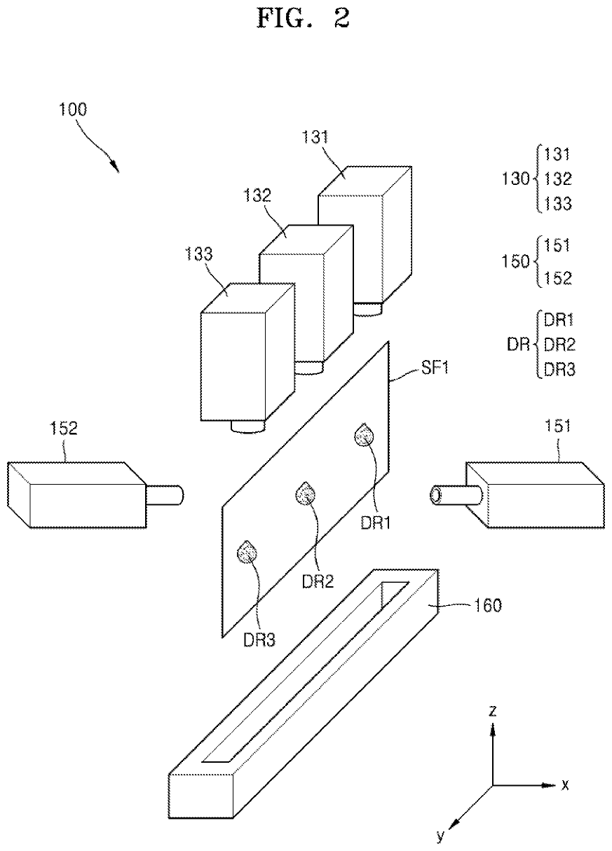

FIG. 1 is a perspective view schematically illustrating an apparatus for manufacturing a display device according to an embodiment, and FIG. 2 is a perspective view schematically illustrating a part of the apparatus for manufacturing a display device shown in FIG. 1.

Referring to FIGS. 1 and 2, an apparatus 100 for manufacturing a display device may include a support unit 110, a gantry 120, a moving unit 130, a droplet ejection unit 140, a detection unit (e.g., a detector) 150, an accommodation unit 160, and a control unit (e.g., a controller) 180.

The support unit 110 may include a stage 111, a guide member 112, a substrate moving member 113, and a substrate rotating member 114. The stage 111 may include an alignment mark for aligning a display substrate S.

The display substrate S may be a substrate used in display devices that are currently manufactured. The display substrate S may include a glass or a polymer resin, such as polyether sulfone, polyacrylate, polyether imide, polyethylene naphthalate, polyethylene terephthalate, polyphenylene sulfide, polyarylate, polyimide, polycarbonate (PC), cellulose triacetate (TAC), or cellulose acetate propionate.

The guide members 112 may be spaced apart from and on either side of the substrate moving member 113. The length of each of the guide members 112 may be greater than a length of an edge of the display substrate S. In such an embodiment, the length of the guide member 112 and the edge length of the display substrate S may be measured in an x axis direction of FIG. 1.

The gantry 120 may be disposed on the guide member 112. In an embodiment, the guide member 112 may include a constant rail so that the gantry 120 may exhibit linear motion in a longitudinal direction of (e.g., along) the guide member 112. For example, the guide member 112 may include a linear motion rail.

The substrate moving member 113 may be disposed on the stage 111. The substrate moving member 113 may extend in the longitudinal direction of the guide member 112. For example, referring to FIG. 1, the substrate moving member 113 may extend in the x axis direction of FIG. 1. In addition, the substrate moving member 113 may include a rail along which the substrate rotating member 114 may make a linear motion. For example, the substrate moving member 113 may include a linear motion rail.

The substrate rotating member 114 may be disposed to be rotatable on (e.g., may be rotatably disposed on) the substrate moving member 113. When the substrate rotating member 114 rotates, the display substrate S disposed on the substrate rotating member 114 also rotates. In an embodiment, the substrate rotating member 114 may rotate around (or about) a rotation axis perpendicular to one surface of the stage 111 on which the display substrate S is seated. When the substrate rotating member 114 rotates around the rotation axis perpendicular to one surface of the stage 111 on which the display substrate S is seated, the display substrate S disposed on the substrate rotating member 114 also rotates around the rotation axis perpendicular to one surface of the stage 111 on which the display substrate S is seated. In such an embodiment, the substrate rotating member 114 may fix the display substrate S after the display substrate S is seated on the stage 111. For example, the substrate rotating member 114 may include one of a vacuum chuck, an electrostatic chuck, and an adhesive chuck.

The gantry 120 may be disposed on the guide member 112. That is, the gantry 120 may be disposed on the guide members 112, which are spaced apart from each other on either side of (e.g., on opposite sides of) the substrate moving member 113.

The gantry 120 may move in the longitudinal direction of the guide member 112. In an embodiment, the gantry 120 may manually move linearly or may automatically move linearly by including a motor, a cylinder, or the like. For example, the gantry 120 may automatically move linearly by including a linear motion block that moves along the linear motion rail.

The moving unit 130 may move linearly on (or along) the gantry 120. For example, the gantry 120 may include a constant rail along which the moving unit 130 may move linearly. In such an embodiment, the droplet ejection unit 140 may be disposed on the moving unit 130 and may move along with the moving unit 130 when the moving unit 130 moves.

The moving unit 130 and the droplet ejection unit 140 may be arranged in various ways. For example, a plurality of moving units 130 and a plurality of droplet ejection units 140 may be provided. In such an embodiment, one droplet ejection unit 140 may be disposed on one moving unit 130, a part of (e.g., one of) a plurality of droplet ejection units 140 may be arranged on one moving unit 130, or another part of (e.g., another one of) the plurality of droplet ejection units 140 may be arranged on another moving unit 130.

In another embodiment, a plurality of droplet ejection units 140 may be provided and one moving unit 130 may be provided. In such an embodiment, the plurality of droplet ejection units 140 may be arranged on one moving unit 130 and may move simultaneously according to the movement of the moving unit 130. In such an embodiment, each of the droplet ejection units 140 may include at least one head including at least one nozzle.

Hereinafter, for convenience of explanation, an embodiment in which a plurality of moving units 130 and a plurality of droplet ejection units 140 are provided and one droplet ejection unit 140 is disposed on one moving unit 130 will be described in detail.

A plurality of moving units 130 may be provided. In such an embodiment, the number of moving units 130 may correspond to the number of droplet ejection units 140. For example, each of the moving units 130 may include a first moving unit 131, a second moving unit 132, and a third moving unit 133.

The first moving unit 131 and the second moving unit 132 may be spaced apart from each other, and the second moving unit 132 and the third moving unit 133 may be spaced apart from each other. A distance between the first moving unit 131 and the second moving unit 132 may be equal to a distance between the second moving unit 132 and the third moving unit 133. In another embodiment, the distance between the first moving unit 131 and the second moving unit 132 and the distance between the second moving unit 132 and the third moving unit 133 may be different from each other. In embodiments described above, the first moving unit 131, the second moving unit 132, and the third moving unit 133 may move independently from each other.

The moving unit 130 may move linearly on (or along) the gantry 120. For example, the moving unit 130 may move in the lengthwise direction of the gantry 120. For example, at least one of the first moving unit 131, the second moving unit 132, and the third moving unit 133 may move in a +y axis direction or −y axis direction of FIG. 1.

In an embodiment, the moving unit 130 may manually move linearly. In another embodiment, the moving unit 130 may automatically move linearly by including a motor, a cylinder, etc. For example, the moving unit 130 may include a linear motion block that moves along the linear motion rail.

The droplet ejection unit 140 may be arranged on the moving unit 130. For example, a first droplet ejection unit 141 may be arranged on the first moving unit 131, a second droplet ejection unit 142 may be arranged on the second moving unit 132, and a third droplet ejection unit 143 may be arranged on the third moving unit 133.

The droplet ejection unit 140 may eject droplets DR into a display substrate S or into an accommodation unit 160. The droplets DR may be ink of red, green, and blue in which pigment particles are mixed with liquid crystal, orientation, and solvent. In another embodiment, the droplets DR may be a polymer or a low molecular weight organic material that corresponds to a light-emitting layer of an organic light-emitting display device. In another embodiment, the droplets DR may include a solution including inorganic particles, such as quantum dot materials or the like.

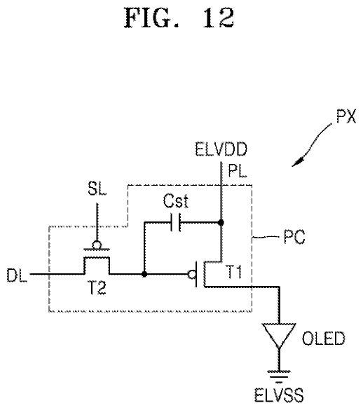

The amount of the droplets DR independently supplied to (or emitted by) each of the first droplet ejection unit 141, the second droplet ejection unit 142, and the third droplet ejection unit 143 may be adjusted. In such an embodiment, each of the first droplet ejection unit 141, the second droplet ejection unit 142, and the third droplet ejection unit 143 may be electrically connected to the control unit 180. Thus, the amount of the droplets DR ejected from each of the first droplet ejection unit 141, the second droplet ejection unit 142, and the third droplet ejection unit 143 may be adjusted by the control unit 180. In the embodiment described above, at least one of the first droplet ejection unit 141, the second droplet ejection unit 142, and the third droplet ejection unit 143 may include at least one nozzle for ejecting one droplet DR. In such an embodiment, when a plurality of nozzles are provided, at least one of the plurality of nozzles may provide droplets DR into an opening (see, e.g., 190P in FIG. 12), to be described later. For example, one nozzle may provide the droplets DR into one opening (see, e.g., 190P in FIG. 12). In another embodiment, at least two nozzles may provide the droplets DR into one opening (see, e.g., 190P in FIG. 12).

The detection unit 150 may detect and measure the shape of the droplets DR ejected by the droplet ejection unit 140. For example, the detection unit 150 may detect and measure the shape of a part of an outer surface of the droplets DR ejected by the droplet ejection unit 140 or may detect and measure the shape of a part of a cross-section of the droplets DR ejected by the droplet ejection unit 140. The detection unit 150 may detect the shape of the outer surface of the droplets DR projected onto a first plane SF1, that is, an arbitrary plane. The detection unit 150 may include a first detection unit 151 and a second detection unit 152.

The first detection unit 151 and the second detection unit 152 may detect the droplets DR ejected from the droplet ejection unit 140 to the accommodation unit 160. The first detection unit 151 and the second detection unit 152 may be arranged on a fall path of the droplets DR that drop from the droplet ejection unit 140. In addition, the first detection unit 151 and the second detection unit 152 may be arranged in opposite directions on the basis of the fall path of the droplets DR. That is, the second detection unit 152 may be disposed opposite to (e.g., facing) the first detection unit 151 with the falling droplets DR therebetween. For example, the first detection unit 151 and the second detection unit 152 may be spaced apart from each other in an x axis direction in FIG. 2.

The first detection unit 151 and the second detection unit 152 may detect the shape of a part of the outer surface of the droplets DR projected onto the first plane SF1. If the shapes of parts of the outer surfaces of the droplets DR detected by the first detection unit 151 and the second detection unit 152 are not connected to each other (e.g., if the first detection unit 151 and the second detection unit 152 do not completely image the outer surface of the droplets DR), the control unit 180 may connect the other portions than the shapes of parts of the outer surfaces of the droplets DR detected by the first detection unit 151 and the second detection unit 152 (e.g., the control unit 180 may extrapolate or generate the missing imaging data of the outer surface of the droplets).

The detection unit 150 may have various shapes. For example, the detection unit 150 may include a confocal microscope, an interferometric microscope, or a chromatic confocal line sensor. The confocal microscope may obtain various two-dimensional images of an object with different depths and is a microscope that reconfigures a three-dimensional structure of the object based these two-dimensional images. The confocal microscope may be, for example, a chromatic confocal microscope, chromatic line confocal microscope, or the like. The interferometric microscope is a microscope that measures and quantified by observing changes in the microstructure of the object and changes in phase. The interferometric microscope may be, for example, a laser interferometric microscope, a white light interferometric microscope, or the like. Hereinafter, for convenience of explanation, an embodiment in which the detection unit 150 includes a confocal line sensor will be described in detail.

The number of droplet ejection units 140 may be greater than the number of detection units 150. The number of one set of detection units 151 and 152 may be less than the number of the droplet ejection units 140. Thus, one detection unit 150 may detect a plurality of droplets at the same time.

In the embodiment shown in FIGS. 1 and 2, three droplet ejection units 140 and one detection unit 150 are provided. However, this is just an example, and the number of droplet ejection units 140 and the number of detection units 150 are not limited thereto. For example, in another embodiment, a plurality of detection units 150 may be provided, and the number of droplet ejection units 140 may be greater than the number of detection units 150.

The accommodation unit 160 may be disposed between the guide members 112. In such an embodiment, the accommodation unit 160 may store droplets DR temporarily when the droplets DR falling from the droplet ejection unit 140 are measured. The accommodation unit 160 may be disposed on the stage 111. In another embodiment, the accommodation unit 160 may also be disposed on a lower surface of the stage 111. In such an embodiment, holes (or openings) may be formed in a portion of the stage 111 at where the accommodation unit 160 is disposed.

In the apparatus 100 for manufacturing the display device, the droplets DR may be supplied to the display substrate S so that an organic material layer may be formed on the display substrate S. In such an embodiment, the droplets DR need to be exactly ejected onto the display substrate S. To confirm this, the droplets DR may be detected by the detection unit 150 while ejecting the droplets DR to the accommodation unit 160 after arranging each droplet ejection unit 140 to correspond to the accommodation unit 160. In another embodiment, each droplet ejection unit 140 may eject the droplets DR onto the display substrate S, and the detection unit 150 may detect the droplets DR. In another embodiment, each droplet ejection unit 140 may be seated on a support plate separately provided at a portion at where the substrate rotation member 114 or the accommodation unit 160 is disposed, and the droplet ejection unit 140 may supply the droplets DR to a test substrate having the same shape as the display substrate S such that the detection unit 150 may detect the droplets DR. However, hereinafter, for convenience of explanation, an embodiment in which the droplet ejection unit 140 ejects the droplets DR onto the accommodation unit 160 and the detection unit 150 detects the droplets DR, will be described in detail.

The control unit 180 may extract (e.g., may determine) the volume of each of the plurality of droplets DR falling from the plurality of droplet ejection units 140 based on the result of measurement using the detection unit 150. The control unit 180 may control at least one of the droplet ejection unit 140 and the moving unit 130 based on the volume (e.g., based on the determined volume) of the droplets DR.

For example, the control unit 180 may control the amount of the droplets DR ejected by the droplet ejection unit 140 and/or an ejection speed of the droplets DR. In addition, the position of the droplet ejection unit 140 may be changed by the moving unit 130 in response to the control unit 180 so that the ejection angle of the droplets DR and the fall path of the droplets DR may be adjusted so that the droplets DR fall at a desired position. In another embodiment, the droplet ejection unit 140 may be cleaned according to the ejection angle of the droplets DR or the fall path of the droplets DR or the moving speed of the display substrate S or the moving speed of the droplet ejection unit 140 may be controlled.

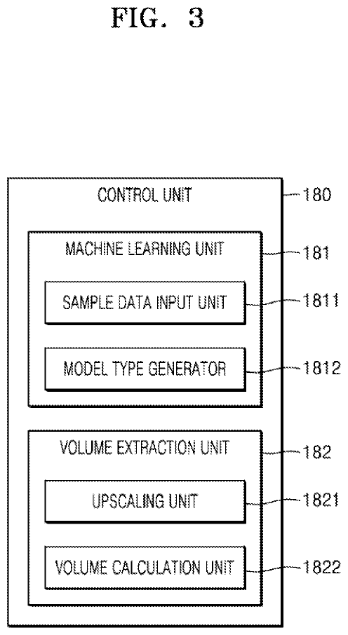

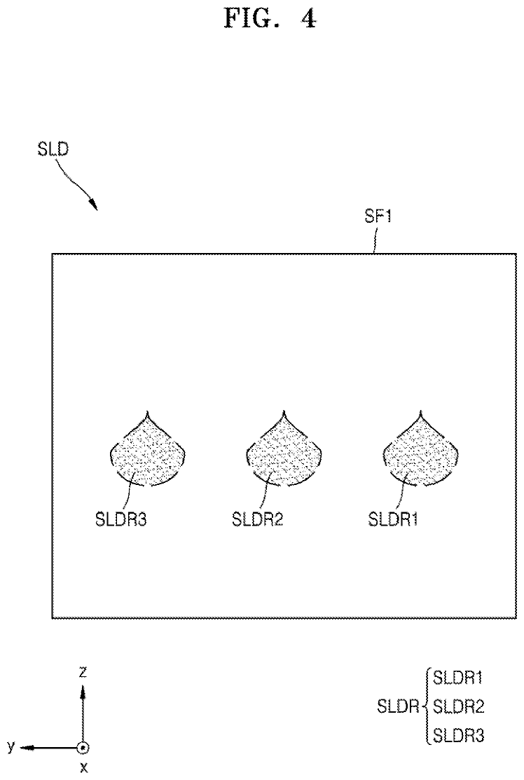

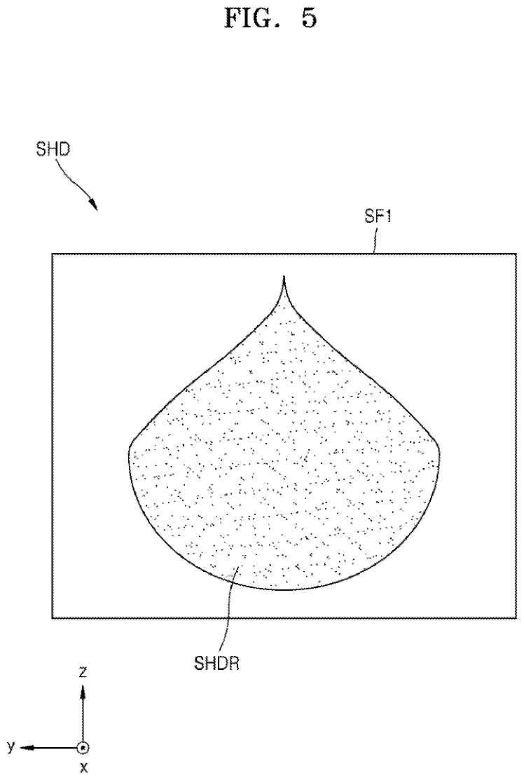

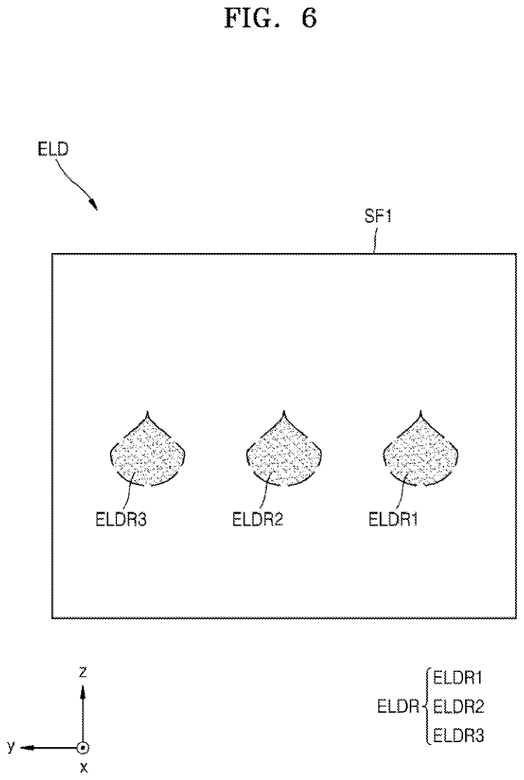

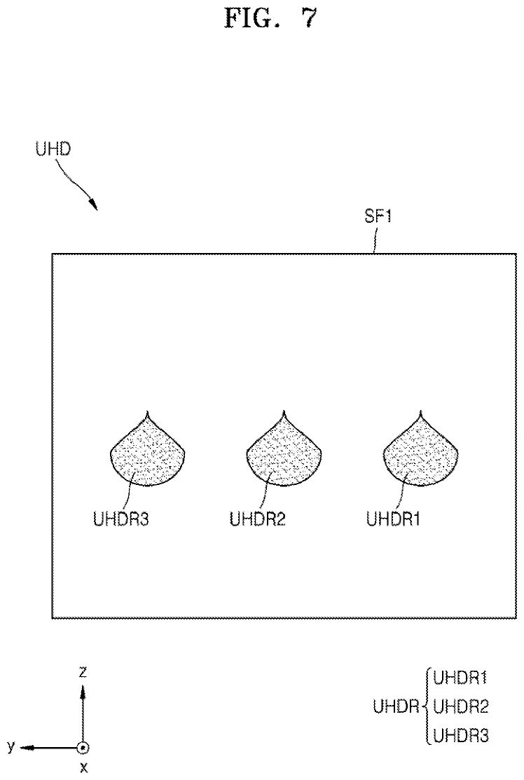

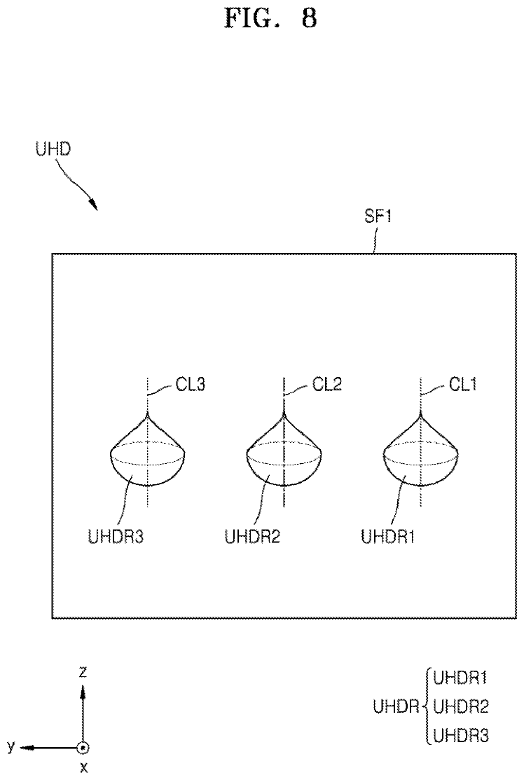

FIG. 3 is a block diagram describing the control unit 180 according to an embodiment, FIG. 4 is a diagram illustrating sample low-resolution data according to an embodiment, FIG. 5 is a diagram illustrating sample high-resolution data according to an embodiment, FIG. 6 is a diagram illustrating detected low-resolution data according to an embodiment, FIG. 7 is a diagram illustrating upscaled high-resolution data according to an embodiment, and FIG. 8 is a diagram illustrating data for extracting (or determining) the volume of droplets according to an embodiment.

Referring to FIGS. 2 through 8, the control unit 180 may extract (e.g., may determine) the volume of each of a plurality of droplets DR based on the detected low-resolution data ELD. The control unit 180 may include a machine learning unit 181 and a volume extraction unit 182.

First, referring to FIGS. 3 through 5, the sample low-resolution data SLD and the sample high-resolution data SHD may be input to the machine learning unit 181 so that the correlation between the sample low-resolution data SLD and the sample high-resolution data SHD may be learned (e.g., may be machine learned) by the machine learning unit 181.

The data input to the machine learning unit 181 is data measured in advance after the droplet ejection unit 140 ejects the droplets DR. For example, the sample low-resolution data SLD and the sample high-resolution data SHD are previously-measured data.

The sample low-resolution data SLD may be data including the shape of a plurality of sample low-resolution droplets SLDR. For example, the sample low-resolution data SLD may be data including the shape of each of first sample low-resolution droplets SLDR1, second sample low-resolution droplets SLDR2, and third sample low-resolution droplets SLDR3.

The sample high-resolution data SHD may be data including the shape of the high-resolution droplets DR corresponding to each of the plurality of sample low-resolution droplets SLDR. The resolution and magnification of the sample high-resolution data SHD may be higher than those of the sample low-resolution data SLD. Thus, the number of sample low-resolution droplets SLDR included in the sample low-resolution data SLD may be greater than the number of sample high-resolution droplets SHDR included in the sample high-resolution data SHD. For example, as shown in FIGS. 4 and 5, the number of sample low-resolution droplets SLDR included in one sample low-resolution data SLD may be three, and the number of sample high-resolution droplets SHDR included in one sample high-resolution data SHD may be one.

However, the number of sample high-resolution data SHD may correspond to the number of a plurality of sample low-resolution droplets SLDR. For convenience, FIG. 5 illustrates only one sample high-resolution data SHD corresponding to the first sample low-resolution droplets SLDR1 in FIG. 4. However, as shown in FIG. 4, when three sample low-resolution droplets SLDR are provided, three sample high-resolution data SHD may be provided.

The machine learning unit 181 may include a sample data input unit 1811 and a model type generator 1812.

The sample low-resolution data SLD and the sample high-resolution data SHD may be input to the sample data input unit 1811. The sample low-resolution data SLD input to the sample data input unit 1811 may be in plural. In addition, the sample high-resolution data SHD input to the sample data input unit 1811 may be in plural, as in (e.g., in a number corresponding to) the sample low-resolution data SLD.

The model type generator 1812 may generate an upscaling model by analyzing the correlation between the sample low-resolution data SLD and the sample high-resolution data SHD.

In such an embodiment, the model type generator 1812 may generate the upscaling model by inputting the sample low-resolution data SLD to an independent variable and by inputting the sample high-resolution data SHD to a dependent variable and analyzing the correlation between the sample low-resolution data SLD and the sample high-resolution data SHD.

Referring to FIGS. 2, 3, and 6 through 8, the volume extraction unit 182 may extract (e.g., may determine) the volume of the plurality of droplets DR by correcting (e.g., by upscaling) the detected low-resolution data ELD into upscaled high-resolution data UHD based on the result of learning performed by the machine learning unit 181.

Here, the detected low-resolution data ELD may be data actually detected by the detection unit 150. The detected low-resolution data ELD may be data including the shape of a plurality of detected low-resolution droplets ELDR. For example, the number of detected low-resolution droplets ELDR may be the same as the number of sample low-resolution droplets SLDR shown in FIG. 4. For example, the detected low-resolution data ELD may be data including the shape of each of first detected low-resolution droplets ELDR1, second detected low-resolution droplets ELDR2, and third detected low-resolution droplets ELDR3.

The upscaled high-resolution data UHD may be data obtained by correcting (e.g., by upscaling) the detected low-resolution data ELD. The upscaled high-resolution data UHD may have a higher resolution than that of the detected low-resolution data ELD.

The volume extraction unit 182 may include an upscaling unit 1821 and a volume calculation unit 1822.

The upscaling unit 1821 may upscale the detected low-resolution data ELD into the upscaled high-resolution data UHD by substituting (or inputting) the detected low-resolution data ELD into the upscaling model. When the detected low-resolution data ELD is substituted into the upscaling model, the resolution and magnification of the detected low-resolution droplets ELDR may be increased. Resolution (e.g., only resolution) may be increased by adjusting magnification again, as shown in FIG. 7.

The volume calculation unit 1822 may calculate the volume of each of the plurality of droplets DR by extracting a plurality of three-dimensional images of the plurality of droplets DR based on the upscaled high-resolution data UHD. As shown in FIG. 8, the volume extraction unit 182 may calculate the three-dimensional shape of the upscaled high-resolution droplets UHDR by rotating an outer surface of the upscaled high-resolution droplets UHDR based on the fall path of the upscaled high-resolution droplets UHDR on the basis of the upscaled high-resolution data UHD. Here, the fall path of the upscaled high-resolution droplets UHDR may be a central axis of the upscaled high-resolution droplets UHDR. In addition, the volume extraction unit 182 may calculate the volume of the droplets DR by using the three-dimensional shape of the upscaled high-resolution droplets UHDR.

For example, the volume extraction unit 182 may rotate the first upscaled high-resolution droplets UHDR1 around a first central axis CL1, rotate the second upscaled high-resolution droplets UHDR2 around a second central axis CL2, and rotate the third upscaled high-resolution droplets UHDR3 around a third central axis CL3, thereby calculating the volume of each of three droplets DR.

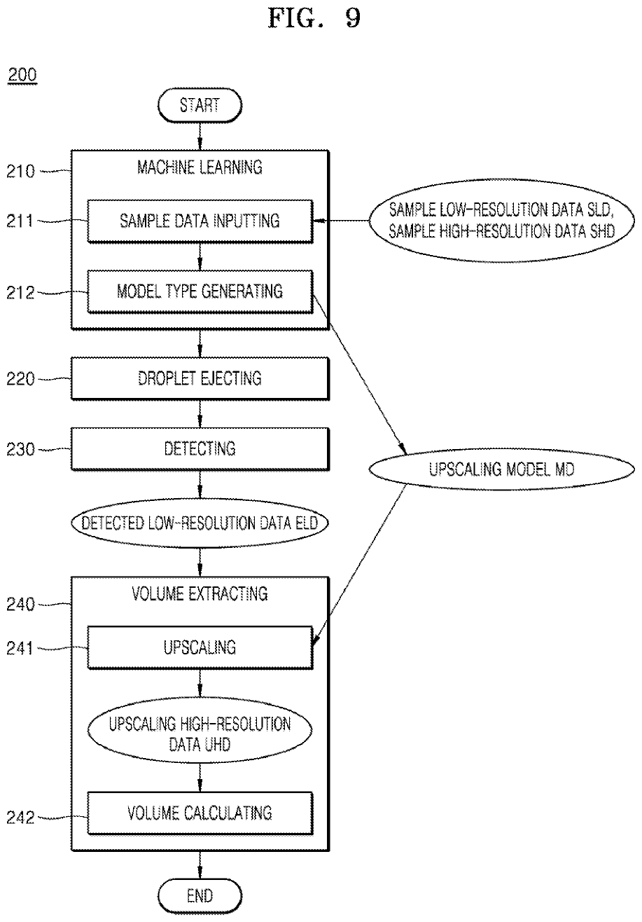

FIG. 9 is a schematic flowchart describing a method of manufacturing a display device according to an embodiment.

In FIG. 9, the same reference numerals as those of FIGS. 1 through 8 represent same elements and, thus, redundant descriptions thereof may be omitted.

Referring to FIG. 9, a method 200 of manufacturing a display device may include machine learning (210), droplet ejecting (220), detecting (230), and volume extracting (240).

In machine learning (210), sample low-resolution data SLD and sample high-resolution data SHD may be input to the machine learning unit (see, e.g., 181 in FIG. 3), and correlation between the sample low-resolution data SLD and the sample high-resolution data SHD may be machine learned.

The machine learning (210) may include sample data inputting (211) and model type generating (212). The sample data inputting (211) may be an operation in which the sample low-resolution data SLD and the sample high-resolution data SHD are input to the sample data input unit (see, e.g., 1811 in FIG. 3). The model type generating (212) may be an operation in which the model type generator (see, e.g., 1812 in FIG. 3) analyzes (or determines) the correlation between the sample low-resolution data SLD and the sample high-resolution data SHD to generate an upscaling model MD.

Droplet ejecting (220) may be an operation in which each of a plurality of droplet ejection units (see, e.g., 140 in FIG. 3) including a nozzle ejects droplets DR. Detecting (230) may be an operation in which a detection unit (see, e.g., 150 in FIG. 3) detects the detected low-resolution data ELD.

Volume extracting (240) may be an operation in which the volume extracting unit (see, e.g., 182 in FIG. 3) extracts (e.g., determines or calculates) the volume of the plurality of droplets DR by correcting (or upscaling) the detected low-resolution data ELD into the upscaled high-resolution data UHD based on the result of learning performed during the machine learning (210).

Volume extracting (240) may include upscaling (241) and volume calculating (242). The upscaling (241) may be an operation in which an upscaling unit (see, e.g., 1821 in FIG. 3) upscales the detected low-resolution data ELD into the upscaled high-resolution data UHD by substituting (or inputting) the detected low-resolution data ELD into the upscaling model MD. The volume calculating (242) may be an operation in which the volume calculating unit (see, e.g., 1822 in FIG. 3) calculates the volume of each of the plurality of droplets DR by extracting three-dimensional images of the plurality of droplets DR based on the upscaled high-resolution data UHD.

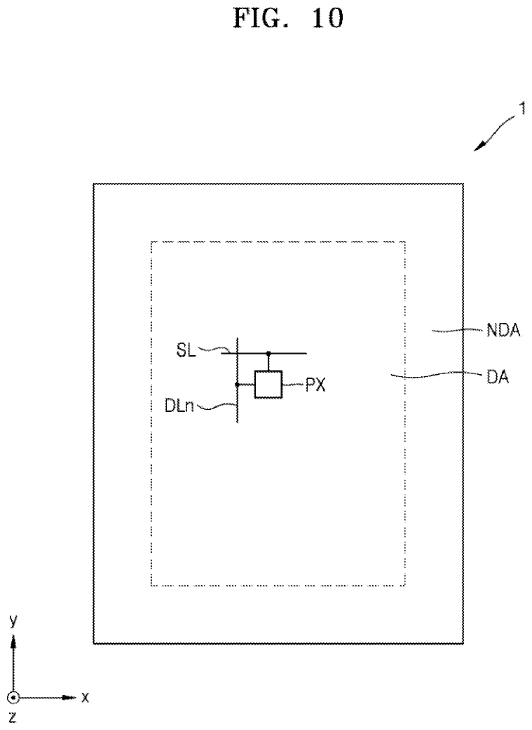

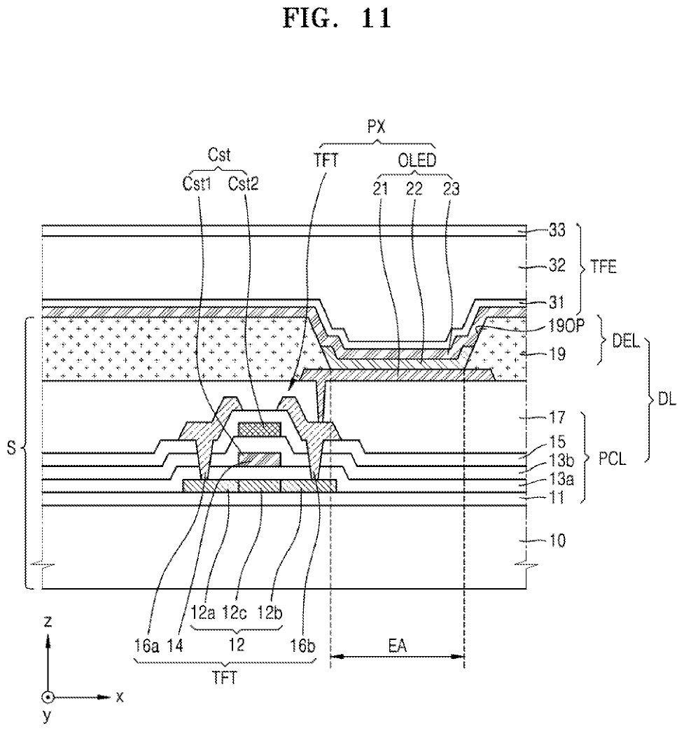

FIG. 10 is a plan view schematically illustrating a display device manufactured by using an apparatus for manufacturing the display device according to an embodiment, and FIG. 11 is a cross-sectional view schematically illustrating the display device manufactured by using an apparatus for manufacturing the display device shown in FIG. 10.

Referring to FIGS. 10 and 11, a display device 1 may include a display substrate S. The display substrate S may include a substrate 10, an intermediate layer of a display layer DL, and a layer excluding a common electrode 23.

The display layer DL and a thin-film encapsulation layer TFE may be arranged on the substrate 10. The display layer DL may include a pixel circuit layer PCL and a display element layer DEL.

The substrate 10 may include a glass or a polymer resin, such as polyether sulfone, polyacrylate, polyether imide, polyethylene naphthalate, polyethylene terephthalate, polyphenylene sulfide, polyarylate, polyimide, polycarbonate (PC), cellulose triacetate (TAC), or cellulose acetate propionate.

A barrier layer may be further disposed between the display layer DL and the substrate 10. The barrier layer, that is, a barrier layer for preventing penetration of external foreign substances, may have a single layer or multi-layered structure including an inorganic material, such as silicon nitride (SiNₓ, where x>0) or silicon oxide (SiOₓ, where x>0).

The pixel circuit layer PCL may be disposed on the substrate 10. The pixel circuit layer PCL may include a thin-film transistor TFT, and a buffer layer 11, a first insulating layer 13a, a second insulating layer 13b, a third insulating layer 15, and a planarization layer 17, which are arranged under or/and on components of the thin-film transistor TFT.

The buffer layer 11 may include an inorganic insulating material, such as silicon nitride, silicon oxynitride, and silicon oxide, and may have a single layer or multi-layered structure including the inorganic insulating materials described above.

The thin-film transistor TFT may include a semiconductor layer 12, and the semiconductor layer 12 may include polysilicon. In another embodiment, the semiconductor layer 12 may include amorphous silicon, an oxide semiconductor, or an organic semiconductor, etc. The semiconductor layer 12 may have a channel region 12c, and a drain region 12a and a source region 12b at both sides (e.g., at opposite sides) of the channel region 12c. A gate electrode 14 may overlap the channel region 12c.

The gate electrode 14 may include a low-resistance metal material. The gate electrode 14 may include a conductive material including molybdenum (Mo), aluminum (AI), copper (Cu), titanium (Ti), or the like, and may have a multi-layered or single layer structure including the materials described above.

The first insulating layer 13a between the semiconductor layer 12 and the gate electrode 14 may include an inorganic insulating material, such as silicon oxide (e.g., SiO₂), silicon nitride (SiNₓ), silicon oxynitride (SiON), aluminum oxide (e.g., Al₂O₃), titanium oxide (e.g., TiO₂), tantalum oxide (e.g., Ta₂O₅), hafnium oxide (e.g., HfO₂), or zinc oxide (e.g., ZnO₂).

The second insulating layer 13b may be provided to cover the gate electrode 14. The second insulating layer 13b may include an inorganic insulating material, such as silicon oxide (e.g., SiO₂), silicon nitride (SiNₓ), silicon oxynitride (SiON), aluminum oxide (e.g., Al₂O₃), titanium oxide (e.g., TiO₂), tantalum oxide (e.g., Ta₂O₅), hafnium oxide (e.g., HfO₂), or zinc oxide (e.g., ZnO₂), similar to the first insulating layer 13a.

An upper electrode Cst2 of a storage capacitor Cst may be disposed above the second insulating layer 13b. The upper electrode Cst2 may overlap the gate electrode 14 thereunder. The gate electrode 14 and the upper electrode Cst2, which overlap each other with the second insulating layer 13b therebetween, may form the storage capacitor Cst. That is, the gate electrode 14 may act as a lower electrode Cst1 of the storage capacitor Cst.

In this way, the storage capacitor Cst and the thin-film transistor TFT may overlap each other. In some embodiments, the storage capacitor Cst may not overlap (e.g., may be offset from) the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may have a single layer or multi-layered structure including the materials described above.

The third insulating layer 15 may be provided to cover the upper electrode Cst2. The third insulating layer 15 may include an inorganic insulating material, such as silicon oxide (e.g., SiO₂), silicon nitride (SiNₓ), silicon oxynitride (SiON), aluminum oxide (e.g., Al₂O₃), titanium oxide (e.g., TiO₂), tantalum oxide (e.g., Ta₂O₅), hafnium oxide (e.g., HfO₂), or zinc oxide (e.g., ZnO₂). The third insulating layer 15 may have a single layer or multi-layered structure including the inorganic insulating materials described above.

Each of a drain electrode 16a and a source electrode 16b may be located on the third insulating layer 15. The drain electrode 16a and the source electrode 16b may include a conductive material (e.g., a good conductive material). The drain electrode 16a and the source electrode 16b may include a conductive material including molybdenum (Mo), aluminum (AI), copper (Cu), titanium (Ti), or the like, and may have a multi-layered or single layer structure including the materials described above. In an embodiment, the drain electrode 16a and the source electrode 16b may have a multi-layered structure of Ti/Al/Ti.

The planarization layer 17 may include an organic insulating material. The planarization layer 17 may include a general-purpose polymer, such as polymethylmethacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene polymer, a vinyl alcohol-based polymer, and an organic insulating material, such as a blend thereof.

The display element layer DEL may be disposed on the pixel circuit layer PCL having the structure described above. The display element layer DEL may include an organic light-emitting diode OLED, and a pixel electrode 21 of the organic light-emitting diode OLED may be electrically connected to the thin-film transistor TFT through a contact hole (e.g., a contact opening) defined in (e.g., extending through) the planarization layer 17.

A pixel PX may include the organic light-emitting diode OLED and the thin-film transistor TFT. Each pixel PX may emit red, green or blue light, for example, through the organic light-emitting diode OLED, or may emit red, green, blue or white light.

The pixel electrode 21 may include a conductive oxide, such as indium tin oxide (ITO), indium zinc oxide (IZO), zinc oxide (ZnO), indium oxide (e.g., In₂O₃), indium gallium oxide (IGO), or aluminum zinc oxide (AZO). In another embodiment, the pixel electrode 21 may include a reflective layer including Ag, Mg, Al, Pt, Pd, Au, Ni, Nd, Ir, Cr, or a compound thereof. In another embodiment, the pixel electrode 21 may further include layers formed of ITO, IZO, ZnO or In₂O₃ on/under the above-described reflective layer.

A pixel-defining layer 19 having an opening 190P exposing a center of the pixel electrode 21 may be disposed on the pixel electrode 21. The pixel-defining layer 19 may include an organic insulating material and an inorganic insulating material. The opening 190P may define an emission area (hereinafter, referred to as an emission area EA) of light emitted from the organic light-emitting diode OLED. For example, the width or diameter of the opening 190P may correspond to the width or diameter of the emission area EA.

A light-emitting layer 22 may be disposed in the opening 190P in the pixel-defining layer 19. The light-emitting layer 22 may include a polymer or a low molecular weight organic material emitting light of a certain color. In another embodiment, the light-emitting layer 22 may include a quantum dot material. The light-emitting layer 22 may be formed by ejecting droplets from the apparatus for manufacturing the display device according to an embodiment.

A first functional layer and a second functional layer may be arranged under and on the light-emitting layer 22, respectively. The first functional layer may include, for example, a hole transport layer (HTL) or a HTL and a hole injection layer (HIL). The second functional layer may be a component or layer disposed on the light-emitting layer 22. The second functional layer may include an electron transport layer (ETL) and/or an electron injection layer (EIL). The first functional layer and/or the second functional layer may be a common layer formed to entirely cover the substrate 10, similar to the common electrode 23, to be described later.

The common electrode 23 may include a conductive material having a low work function. For example, the common electrode 23 may include a (semi-) transparent layer including Ag, Mg, Al, Pt, Pd, Au, Ni, Nd, Ir, Cr, Li, Ca or an alloy thereof. In another embodiment, the common electrode 23 may further include a layer, such as ITO, IZO, ZnO or In₂O₃, on the (semi-) transparent layer including the above-described materials.

The thin-film encapsulation layer TFE may be disposed on the common electrode 23. In an embodiment, the thin-film encapsulation layer TFE may include at least one inorganic encapsulation layer and at least one organic encapsulation layer, and FIG. 11 illustrates an embodiment in which the thin-film encapsulation layer TFE includes a first inorganic encapsulation layer 31, an organic encapsulation layer 32, and a second inorganic encapsulation layer 33, which are sequentially stacked.

The first inorganic encapsulation layer 31 and the second inorganic encapsulation layer 33 may include one or more inorganic materials from among aluminum oxide, titanium oxide, tantalum oxide, hafnium oxide, zinc oxide, silicon oxide, silicon nitride, and silicon oxynitride. The organic encapsulation layer 32 may include a polymer-based material. The polymer-based material may include an acryl-based resin, an epoxy-based resin, polyimide, polyethylene, or the like. In an embodiment, the organic encapsulation layer 32 may include acrylate.

In another embodiment, the thin-film encapsulation layer TFE may have a structure in which the substrate 10 and an upper substrate, as a transparent member, are coupled to each other as a sealing member and an inner space between the substrate 10 and the upper substrate is sealed. A moisture absorbent or filling materials may be arranged in the inner space. The sealing member may be a sealant, and in another embodiment, the sealing member may include a material curable by a laser. For example, the sealing member may be frit. In some embodiments, the sealing member may be a urethane-based resin, an epoxy-based resin, an acryl-based resin, which are organic sealants, or silicon, which is an inorganic sealant. The urethane-based resin may be, for example, urethane acrylate or the like. The acryl-based resin may be, for example, butyl acrylate, ethylhexyl acrylate, or the like. The sealing member may include a material curable by heat.

FIG. 12 is an equivalent circuit diagram of a pixel of the display panel shown in FIGS. 10 and 11 according to an embodiment.

Each pixel PX may include a pixel circuit PC, a display element connected to the pixel circuit PC, for example, the organic light-emitting diode OLED. The pixel circuit PC may include a first thin-film transistor T1, a second thin-film transistor T2, and a storage capacitor Cst. Each pixel PX may emit, for example, red, green, blue, or white light through the organic light-emitting diode OLED.

The second thin-film transistor T2, that is, a switching thin-film transistor, may be connected to a scan line SL and a data line DL and may be configured to transmit a data voltage input from the data line DL in response to a switching voltage input from the scan line SL to the first thin-film transistor T1. The storage capacitor Cst may be connected to the second thin-film transistor T2 and a driving voltage line PL and may store a voltage corresponding to a difference between a voltage transmitted from the second thin-film transistor T2 and a first power supply voltage ELVDD supplied to the driving voltage line PL.

The first thin-film transistor T1 may be a driving thin-film transistor, may be connected to the driving voltage line PL and the storage capacitor Cst, and may control a driving current flowing through the organic light-emitting diode OLED from the driving voltage line PL in response to a voltage value stored in the storage capacitor Cst. The organic light-emitting diode OLED may emit light having certain luminance by using (or according to) the driving current. An opposite electrode (e.g., a cathode) of the organic light-emitting diode OLED may receive a second power supply voltage ELVSS.

FIG. 12 illustrates an embodiment in which the pixel circuit PC includes two thin-film transistors and one storage capacitor, but embodiments of the present disclosure are not limited thereto. The number of thin-film transistors and the number of storage capacitors may be variously changed according to the design of the pixel circuit PC. For example, the pixel circuit PC may include four, five, or more thin-film transistors in addition to the two thin-film transistors described above.

According to embodiments of the present disclosure, a measurement time of the volume of droplets may be reduced, and the accuracy of the measurement may be enhanced.

It should be understood that the embodiments described herein should be considered in a descriptive sense and not for purposes of limitation. Descriptions of features or aspects within each embodiment should typically be considered as available for other similar features or aspects in other embodiments. While embodiments of the present disclosure have been described with reference to the figures, it will be understood by those of ordinary skill in the art that various changes in form and details may be made therein without departing from the spirit and scope as defined by the following claims and their equivalents.

What is claimed is:

1. An apparatus for manufacturing a display device, the apparatus comprising:
a plurality of droplet ejection units, each comprising a nozzle for ejecting droplets;
a detection unit arranged on a fall path of a plurality of droplets falling from the plurality of droplet ejection units and configured to detect low-resolution data comprising a shape of the plurality of droplets; and
a control unit configured to determine a volume of each of the plurality of droplets based on the detected low-resolution data, the control unit comprising:
a machine learning unit configured to perform machine learning to determine a correlation between sample low-resolution data and sample high-resolution data, the sample low-resolution data comprising a shape of a plurality of sample low-resolution droplets, the sample high-resolution data comprising a shape of high-resolution droplets corresponding to each of the plurality of sample low-resolution droplets input to the machine learning unit; and
a volume extraction unit configured to determine a volume of the plurality of droplets by upscaling the detected low-resolution data into upscaled high-resolution data based a result of learning by the machine learning unit, and
wherein the sample high-resolution data has a magnification greater than a magnification of the sample low-resolution data.

2. The apparatus of claim 1, wherein the machine learning unit comprises:
a sample data input unit to which the sample low-resolution data and the sample high-resolution data are input; and
a model type generator configured to generate an upscaling model by analyzing the correlation between the sample low-resolution data and the sample high-resolution data.

3. The apparatus of claim 2, wherein the volume extraction unit comprises:
an upscaling unit configured to upscale the detected low-resolution data with the upscaled high-resolution data by substituting the detected low-resolution data into the upscaling model; and
a volume calculation unit configured to calculate a volume of each of the plurality of droplets by extracting a three-dimensional image of the plurality of droplets based on the upscaled high-resolution data.

4. The apparatus of claim 1, wherein a number of the droplet ejection units is greater than a number of the detection units.

5. The apparatus of claim 1, wherein the detection unit comprises:
a first detection unit; and
a second detection unit facing the first detection unit with the plurality of droplets therebetween.

6. The apparatus of claim 5, wherein the first detection unit and the second detection unit are each configured to detect a shape of a part of an outer surface of the droplets projected on an arbitrary plane.

7. The apparatus of claim 6, wherein the control unit is configured to calculate the outer surface of the droplets by connecting portions other than the shape of the part of the outer surface of the droplets detected by the first detection unit and the second detection unit.

8. The apparatus of claim 7, wherein the volume extraction unit is configured to calculate a three-dimensional shape of the droplets by rotating the calculated outer surface of the droplets based on the fall path of the droplets and to calculate the volume of the droplets by using the calculated three-dimensional shape of the droplets.

9. The apparatus of claim 1, wherein the detection unit comprises a confocal microscope or a confocal sensor.

10. The apparatus of claim 1, further comprising an accommodation unit configured to store the plurality of droplets emitted from the plurality of droplet ejection units.

11. A method of manufacturing a display device, the method comprising:
inputting, into a machine learning unit, sample low-resolution data comprising a shape of a plurality of sample low-resolution droplets and sample high-resolution data comprising a shape of high-resolution droplets corresponding to each of the plurality of sample low-resolution droplets to perform machine learning to determine a correlation between the sample low-resolution data and the sample high-resolution data;
ejecting droplets by using each of a plurality of droplet ejection units along a fall path, each of which comprises a nozzle;
detecting, by a detection unit, low-resolution data comprising a shape of a plurality of droplets falling from the plurality of droplet ejection units; and
extracting, by a volume extraction unit, a volume of the plurality of droplets by upscaling the detected low-resolution data into upscaled high-resolution data based a result of learning by the machine learning unit,
wherein the sample high-resolution data has a magnification greater than a magnification of the sample low-resolution data.

12. The method of claim 11, wherein the machine learning comprises:
inputting sample data comprising the sample low-resolution data and the sample high-resolution data; and
model type generating an upscaling model by analyzing the correlation between the sample low-resolution data and the sample high-resolution data.

13. The method of claim 12, wherein the volume extracting comprises:
upscaling, in which the detected low-resolution data is upscaled into the upscaled high-resolution data by substituting the detected low-resolution data into the upscaling model; and
volume calculating in which a volume of each of the plurality of droplets is calculated by extracting a three-dimensional image of the plurality of droplets based on the upscaled high-resolution data.

14. The method of claim 11, wherein a number of the droplet ejection units is greater than a number of the detection units.

15. The method of claim 11, wherein the detection unit comprises:
a first detection unit; and
a second detection unit facing the first detection unit with the plurality of droplets therebetween.

16. The method of claim 15, wherein the first detection unit and the second detection unit are each configured to detect a shape of a part of an outer surface of the droplets projected on an arbitrary plane.

17. The method of claim 16, wherein the volume extracting comprises calculating the outer surface of the droplets by connecting portions other than the shape of the part of the outer surface of the droplets detected by the first detection unit and the second detection unit.

18. The method of claim 17, wherein the volume extracting comprises calculating a three-dimensional shape of the droplets by rotating the calculated outer surface of the droplets based on the fall path of the droplets and calculating the volume of the droplets by using the calculated three-dimensional shape of the droplets.

19. The method of claim 11, wherein the detection unit comprises a confocal microscope or a confocal sensor.

20. The method of claim 11, further comprising storing, in an accommodation unit, the plurality of droplets falling from the plurality of droplet ejection units.
